(19) United States
(12) Patent Application Publication
(10) Pub. No.: US 2013/0033282 A1
(43) Pub. Date: Feb. 7, 2013

(54) CONTACT STRUCTURE AND METHOD OF MANUFACTURING CONTACT STRUCTURE

(71) Applicants: Yohei Sato, Tokyo (JP); Tomohisa Hoshino, Nirasaki-shi (JP)

(72) Inventors: Yohei Sato, Tokyo (JP); Tomohisa Hoshino, Nirasaki-shi (JP)

(73) Assignee: Tokyo Electron Limited, Minato-ku (JP)

(21) Appl. No.: 13/641,305

(22) PCT Filed: Apr. 6, 2011
(86) PCT No.: PCT/JP11/58718

§ 371 Date: Oct. 15, 2012

(30) Foreign Application Priority Data
Apr. 15, 2010 (JP) 2010-093733

(51) Int. Cl. G01R 1/067; C25D 1/00

(52) U.S. Cl. 324/755.01; 205/78

(57) ABSTRACT

A contact structure has a probe and a housing disposed on an outer circumference thereof. The housing has a housing main body in which a hollow section vertically penetrating the same is formed, and a conductive coat film with which an inner wall surface of the hollow section is coated. The probe has a base end portion fixed in place on one end side of the housing, a conductive leading end portion that is movable in the hollow section while being in contact with the coat film and has, on a leading end thereof, a contact that comes into contact with a subject to be inspected, and an elastic portion that connects together the base end portion and the leading end portion, is disposed in the hollow section, and has elasticity.

### TECHNICAL FIELD

The present invention relates to a contact structure, which comes into contact with a subject to be inspected so as to inspect electrical characteristics of the subject to be inspected, and a method of manufacturing the contact structure.

### BACKGROUND ART

Electrical characteristics of an electronic circuit such as an IC or an LSI formed on a semiconductor wafer (hereafter referred as a “wafer”) are usually inspected using a probe unit. The probe unit is constructed such that multiple probes are supported on a lower surface of a probe card. Electrical characteristics of a wafer are inspected by bringing leading ends of the multiple probes into a plurality of electrodes in the electronic circuit, and sending and receiving electric signals between needles and the electrodes.

In this inspection, needles for transmitting electric signals supplied from a tester are temporarily brought into contact with fine electrodes formed on a semiconductor device. The needles have elasticity so as to ensure contact pressure required for obtaining desired contact resistance and absorbing mechanical height variances. Conventionally, a cantilever type and a vertical spring pogo pin type have been typically used as probe shape, and recently, those equipped with fine springs using MEMS technology have been becoming mainstream.

In recent years, as semiconductor devices have been miniaturized and increased in performance and functionality, performance required for probes used in inspection has been increasing year after year. For example, with miniaturization of device electrodes, it is necessary to make needles physically small in size, but this also results in deterioration in spring elasticity and a decrease in the allowable amount of electric current. On the other hand, the amount of spring extension and contraction required for inspection is substantially constant, and a large amount of electric current is required according to increased performance and functionality of the device. Therefore, probes satisfying these requirements at the same time are needed.

Based on this concept, a pogo pin probe as described in, for example, Patent Literature 1 has been widely used. A cylindrical portion, which is an electric current path, and a spring are combined together and fixed to a punched housing when they are used.

### CITATION LIST

### Patent Literature

{PTL 1} Japanese Laid-Open Patent Publication (Kokai) No. 2003-344450

### SUMMARY OF INVENTION

### Technical Problem

However, it takes time and effort to manufacture the probe as described in Patent Literature 1 mentioned above because many manual steps are required, and moreover, there is a limit to miniaturization from a machining viewpoint, and responding to increased performance and functionality is difficult.

It is an object of the present invention to provide a contact structure which enables a sufficient amount of electric signals to be sent and received in a stable manner between electrodes and probes brought into contact with the electrodes, and can be easily manufactured, and a method of manufacturing the contact structure.

### Solution to Problem

To solve the above problem, the present invention provides a contact structure that comes into contact with a subject to be inspected so as to inspect electrical characteristics of the subject to be inspected, comprising a probe and a housing disposed on an outer circumference of said probe, wherein the housing comprises a housing main body in which a hollow section vertically penetrating the same is formed, and a conductive coat film with which an inner wall surface of the hollow section is coated, and wherein the probe comprises a base end portion whose position is fixed on one end side of the housing, a conductive leading end portion that is movable in the hollow section while being in contact with the coat film and has a contact that comes into contact with the subject to be inspected, and an elastic portion that connects together the base end portion and the leading end portion, is disposed in the hollow section, and has elasticity.

Further, the present invention provides a method of manufacturing a contact structure that comes into contact with a subject to be inspected so as to inspect electrical characteristics of the subject to be inspected, the contact structure comprising a probe and a housing disposed on an outer circumference of said probe, wherein the housing comprises a housing main body in which a hollow section vertically penetrating the same is formed, and a conductive coat film with which an inner wall surface of the hollow section is coated, wherein the probe comprises a base end portion fixed in place on one end side of the housing, a conductive leading end portion that is movable in the hollow section while being in contact with the coat film and has, on a leading end thereof, a contact that comes into contact with the subject to be inspected, and an elastic portion that connects together the base end portion and the leading end portion, is disposed in the hollow section, and has elasticity, and wherein the probe is formed by molding the leading end portion and the base end portion by electroforming on a substrate on which a conductive material is laid, forming a mold film on the substrate to form on the mold film a pattern having a shape that matches the elastic portion, and molding the elastic portion into the pattern by electrolytic deposition.

Another aspect of the present invention provides a method of manufacturing a contact structure that comes into contact with a subject to be inspected so as to inspect electrical characteristics of the subject to be inspected, the contact structure comprising a probe and a housing disposed on an outer circumference of said probe, wherein the housing comprises a housing main body in which a hollow section vertically penetrating the same is formed, and a conductive coat film with which an inner wall surface of the hollow section is coated, wherein the probe comprises a base end portion fixed in place on one end side of the housing, a conductive leading end portion that is movable in the hollow section while being in contact with the coat film and has, on a leading end thereof, a contact that comes into contact with the subject to be inspected, and an elastic portion that connects together the base end portion and the leading end portion, is disposed in the hollow section, and has elasticity, wherein the elastic portion is made of silicon resin, and wherein the probe is formed by molding the leading end portion and the base end portion by electroforming on a substrate on which a conductive material is laid, forming a mold film on another substrate having a silicon active layer to form on the mold film a pattern having a shape that matches the elastic portion, etching the active layer using the pattern as a mask to mold the elastic portion, and combining the substrate, on which the leading end portion and the base end portion are molded, and the other substrate, on which the elastic portion is molded, together to perform transfer.

### Advantageous Effects of Invention

According to the present invention, because the coat film of the housing acts as an electric current path, and the probe and the housing which are required to have elasticity are configured as separate bodies, the degree of flexibility in selecting the material of the elastic portion can be increased, and miniaturization can be realized by using a material that can be easily molded. Further, the electric current path in the housing enables a large amount of electric current to be sent and received in a stable manner.

### BRIEF DESCRIPTION OF DRAWINGS

FIG. 1 is a side view schematically showing an arrangement of a probe unit.

FIG. 2 is a longitudinal sectional view showing a contact structure according to an embodiment of the present invention.

FIG. 3 is a cross-sectional view showing an exemplary shape of a housing hollow section appearing in FIG. 1.

FIG. 4 is a cross-sectional view showing another exemplary shape of the housing hollow section appearing in FIG. 1.

FIG. 5 is a longitudinal sectional view showing a contact structure according to another embodiment of the present invention.

FIG. 6 is a view useful in explaining an exemplary probe manufacturing procedure according to the present invention.

FIG. 7 is a view useful in explaining another exemplary probe manufacturing procedure according to the present invention.

FIG. 8 is a longitudinal sectional view showing a variation of the contact structure according to the present invention.

FIG. 9 is a longitudinal sectional view showing another variation of the contact structure according to the present invention.

### DESCRIPTION OF EMBODIMENTS

Embodiments of the present invention will now be described with reference to the drawings. It should be noted that in the present specification and the drawings, elements having substantially the same functional arrangements are designated by the same reference symbols, and duplicate description thereof is omitted.

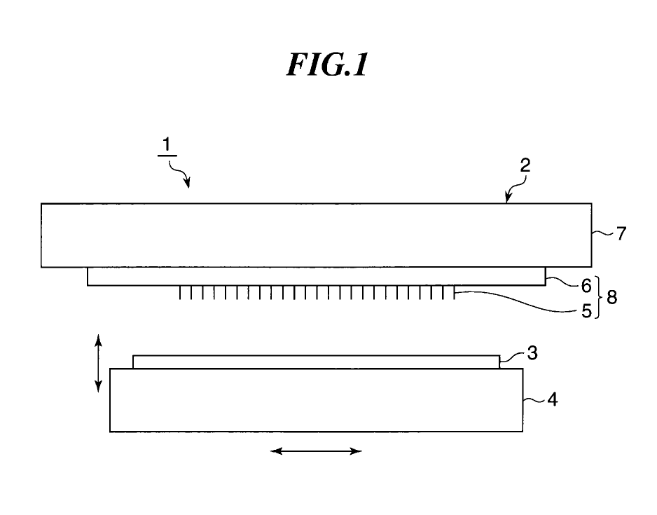

FIG. 1 is a side view schematically showing an arrangement of a probe unit 1 for which a contact structure according to the present invention is used. The probe unit 1 is equipped with, for example, a probe card 2, and a mounting stage 4 on which a subject to be inspected 3 such as a wafer is mounted. The mounting stage 4 is movable vertically and horizontally. The probe card 2 has, for example, a plurality of probes 5, a housing 6 that supports the probes 5, and a circuit board 7 that sends and receives electric signals to and from the probes 5. The housing 6 is, for example, disk-shaped and opposed to the mounting stage 4 below. It should be noted that in the present embodiment, the probes 5 and the housing 6 constitute a contact structure 8.

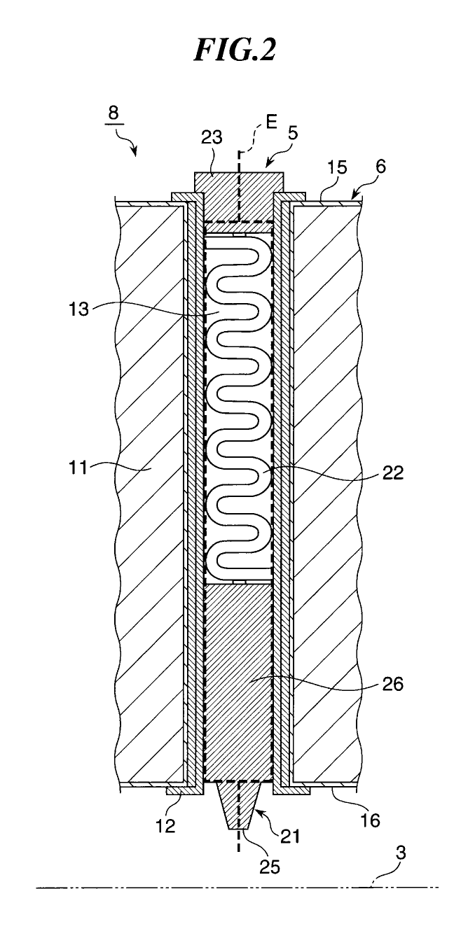

FIG. 2 shows an exemplary contact structure according to the present invention. The contact structure 8 is comprised of the probe 5 and the housing 6 configured as separate bodies.

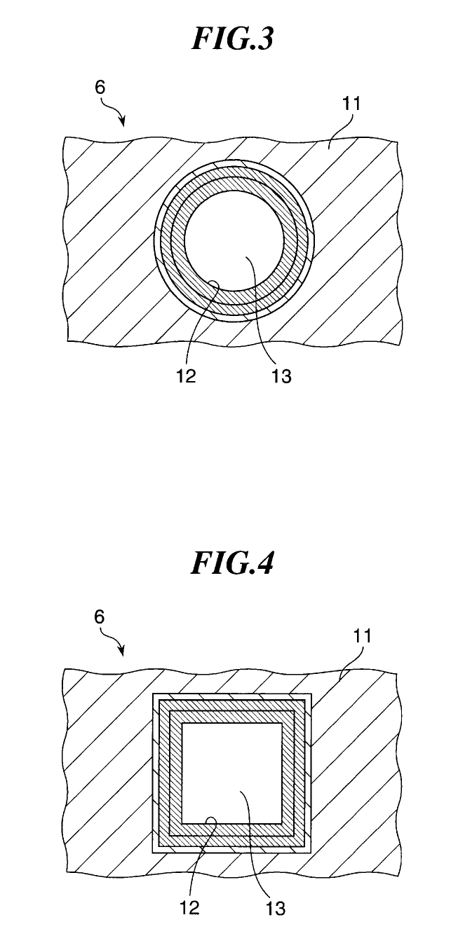

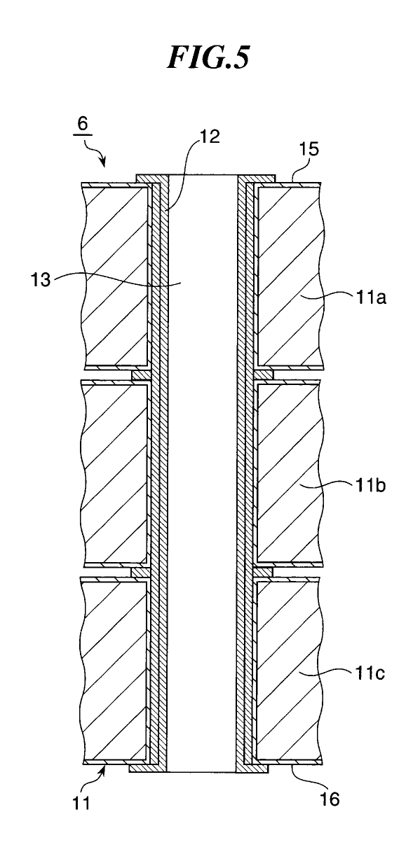

The housing 6 has a housing main body 11 and a coat film 12. The housing main body 11 is formed of, for example, an insulating material such as silicon resin and having a surface layer thereof coated with SiO₂. A cylindrical hollow section 13 vertically penetrating the housing main body 11 is formed in the housing main body 11 by, for example, dry etching. A cross-sectional shape of the hollow section 13 may be circular as shown in FIG. 3, rectangular as shown in FIG. 4, or polygonal as long as the hollow section 13 cylindrically penetrates the housing main body 11. The hollow section 13 has an inner wall surface thereof plated with the coated film 12 made of a conductive material. The coat film 12 may be provided on part of both upper and lower end faces 15 and 16 of the housing main body 11 as shown in the figure as well as on the inner wall surface of the hollow section 13. The material of the coat film 12 is one having conductivity, and for example, having a double-layer structure as shown in the figure, and the entire inner wall surface of the hollow section 13 is plated with Cu, Ni, or the like, and further, the surface of the hollow section 13 and part of the both upper and lower end faces 15 and 16 of the housing main body 11 are plated with Au. The thickness of the coat film 12 is, for example, about 10 μm. Preferably, the coat film 12 on the surface layer side, that is, on the side which contacts the probe 5 is firm, resistant to wear, and resistant to oxidizing, and more preferably, made of Rh, Pt, Ru, or the like as well as Au. The coat film 12 may be configured as a single layer structure comprised of any of these materials.

FIG. 5 shows another exemplary embodiment of the housing main body 11, according to which the housing main body 11 is formed by stacking a plurality of layers 11a, 11b, and 11c in the direction of a vertical axial line. The layers 11a, 11b, and 11c are joined together by plating interlayer gaps with part of the coat film 12 comprised of Au or the like. On this occasion, in order to prevent electricity from passing through other adjacent hollow sections 13 via Au plating, Au plating is given within such a range as not to reach the other hollow sections 13 of the housing main body 11. Alternatively, the layers 11a, 11b, and 11c may be adhered together by injecting an adhesive agent between the layers. The housing main body 11, which is a main subject of the present invention, is fine because the vertical thickness of the housing main body 11 is 1 mm, and the diameter of the hollow section 13 is about 70 μm, and as shown in FIG. 5, forming the housing main body 11 by stacking a plurality of layers such as three layers or two layers to make each layer thinner can further facilitate penetration machining such as dry etching or laser machining that forms the hollow section 13.

It should be noted that the housing main body 11 should not necessarily be made of an insulating material, but may be formed by, for example, inserting an insulating pipe into a metallic housing. Moreover, the coat film 12 made of a conductive material provided on the hollow section 13 should not necessarily be provided on the entire inner wall surface as shown in FIGS. 2 and 4 as long as a base end portion and a leading end portion can be electrically connected together.

As shown in FIG. 2, the probe 5 is comprised of a leading end portion 21 having a contact 25 which contacts the subject to be inspected 3, a base end portion 23 fixed to one end of the housing 6, and an elastic portion 22 that connects the leading end portion 21 and the base end portion 23 together. The leading end portion 21 and the base end portion 23 are each made of a conductive material. The elastic portion 22 is, for example, spring-shaped as shown in FIG. 2 and may be made of metal, but may be made of an insulating material such as silicon resin or organic insulator because the coat film 12 of the housing 6 acts as an electric current path E indicated by a broken line in FIG. 2.

The contact 25 of the leading end portion 21 of the probe 5 has a shape appropriate to the subject to be inspected 3. A shaft portion 26 is formed to have the same cross-sectional shape as that of the hollow section 13 provided with the coat film 12 so that the shaft portion 26 can vertically move along the hollow section 13 while being in contact with the coat film 12 of the housing 6. In order that the coat film 12 of the housing 6 can act as an electric current path, it is absolutely necessary to bring the shaft portion 26 into contact with the coat film 12 so as to bring the leading end portion 21 and the coat film 12 into electrical conduction, and accordingly, for example, the central axis of the shaft portion 26 may be disposed slightly tilted relative to the central axis of the housing 6 so that at least one point of the shaft portion 26 can be in contact with the coat film 12.

The base end portion 23 of the probe 5 is fixed to an end face of the housing 6 while being in contact with the coat film 12. The coat film 12 and the base end portion 23 are brought into electrical conduction by the base end portion 23 and the coat film 12 coming into contact with other. As a result, the electric current path E is formed from the base end portion 23 to the leading end portion 21 of the probe 5 through the coat film 12, and electric signals can be sent and received between the circuit board 7 (see FIG. 1) and the subject to be inspected 3 through the electric current path E.

The elastic portion 22 is vertically elastic, and at the time of bringing the contact 25 of the leading end portion 21 into contact with the subject to be inspected 3, gives a contact pressure required to obtain desired contact resistance and absorbs mechanical height variances.

Next, a description will be given of an exemplary method for manufacturing the probe 5 described above.

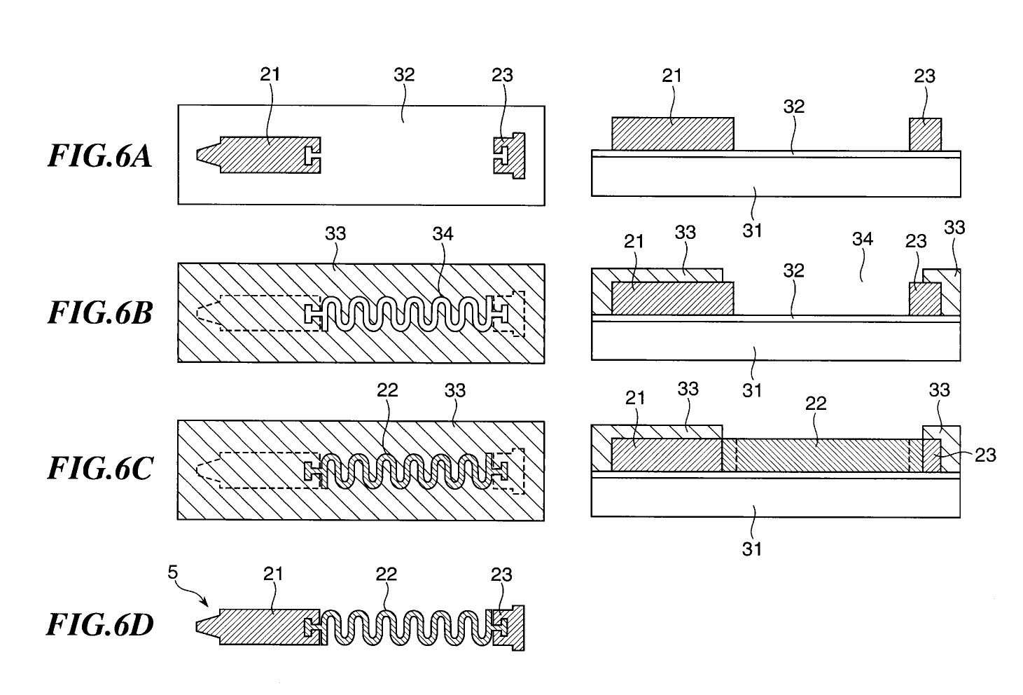

FIG. 6 shows an exemplary manufacturing procedure in a case where the elastic portion 22 of the probe 5 is formed by electrolytic deposition, in which plan views are on the left-hand side, and schematic longitudinal sectional views are on the right-hand side. First, as shown in FIG. 6(a), a conductive material 32, for example, Cu or Ni is laid on a substrate 31 such as a wafer, and the leading end portion 21 and the base end portion 23 are molded by electroforming. Then, as shown in FIG. 6(b), a mold film 33 comprised of, for example, a resist film is formed on the leading end portion 21, the base end portion 23, and the substrate 31 using, for example, a photolithography process, and a pattern 34 having a shape that matches the elastic portion 22 is formed at a position of the mold film 33 which corresponds to the elastic portion 22. Thereafter, as shown in FIG. 6(c), the shape of the elastic portion 22 is molded by electrolytic deposition along the pattern 34 of the mold film 33. Finally, by peeling off the mold film 33, the probe 5 shown in FIG. 6(d) is completed. This method can form the probe 5 having the elastic portion 22 made of, for example, an acrylic or polyimide-based organic insulator.

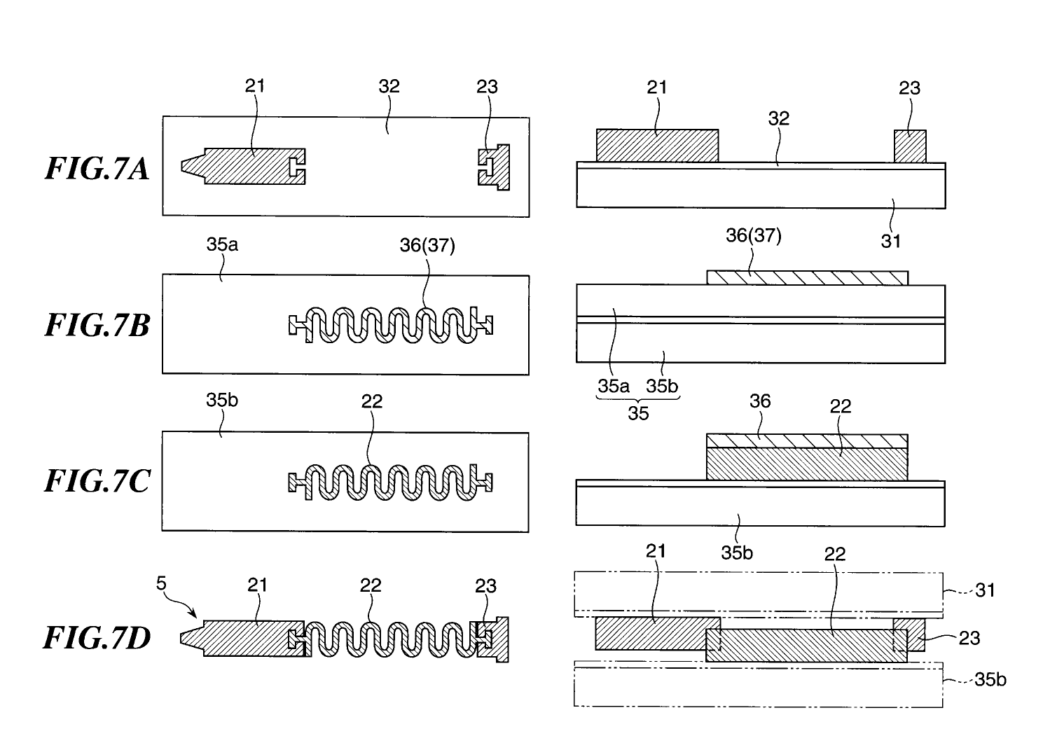

FIG. 7 shows an exemplary procedure for manufacturing the probe 5 in a case where the elastic portion 22 is made of silicon resin, in which as with FIG. 6, plan views are on the left-hand side, and schematic longitudinal sections are shown on the right-hand side. Referring to FIG. 7(a), the conductive material 32, for example, Cu or Ni is laid on the substrate 31, and the leading end portion 21 and the base end portion are molded by electroforming in the same way as in the above described procedure. Then, as shown in FIG. 7(b), a mold film 36 comprised of, for example, a resist film is formed using, for example, a photolithography process on a supporting substrate 35 different from the one shown in FIG. 7(a), and a pattern 37 having a shape that matches the elastic portion 22 is formed at a position of the mold film 36 which corresponds to the elastic portion 22. This supporting substrate 35 is made of two-layer silicon resin, and an SiO₂ film is provided between an upper active layer 35a and a lower layer 35b. The active layer 35a is then etched using the pattern 37 as a mask, and as a result, the elastic portion 22 is molded in the active layer 35a as shown in FIG. 7(c). Finally, as shown in FIG. 7(d), the leading end portion 21 and the base end portion 23 molded as shown in FIG. 7(a) and the elastic portion 22 molded as shown in FIG. 7(c) are combined together to perform transfer, so that the probe 5 is completed.

As described above, according to the present invention, the probe 5 and the housing 6 are configured as separate bodies, so that the probe 5 plays a role in ensuring elasticity and contact pressure, and the housing 6 fixes the probe 5 and acts as an electric current path. As a result, the degree of flexibility in selecting the material of the elastic portion 22 of the probe 5 is increased, and for example, by selecting a material that can be easily microfabricated by photolithography or the like, the fine elastic portion 22 can be easily manufactured.

Moreover, for the housing 6, at the same time as when the housing main body 11 is punched, the coat film 12 can be easily formed by plating it with a metallic material which acts as an electric current path. Therefore, according to the present invention, costs involved in manufacturing the fine probes 5 can be reduced. Further, because the coat film 12 acts as an electric current path, a large amount of electric current can be sent and received in a stable manner. Thus, miniaturization and high performance can be realized at the same time.

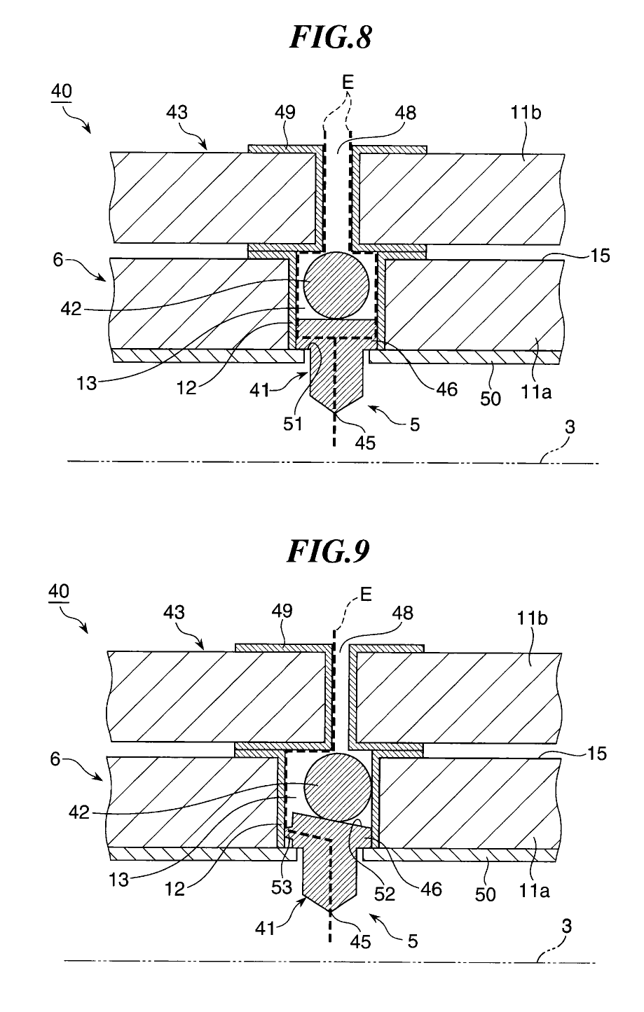

Further, in the present invention, the elastic portion used for the probe should not necessarily be spring-shaped as described above. FIG. 8 shows another exemplary embodiment of the contact structure.

As shown in FIG. 8, in the present embodiment, the probe 5 has a spherical or cylindrical elastic portion 42 made of elastomer. As with the embodiment described above, a leading end portion 41 of the probe 5 has a contact 45 which comes into contact with the subject to be inspected 3 and a shaft portion 46 which is in contact with the coat film 12 of the housing 6, and the entire leading end portion 41 is made of a conductive material.

In the present embodiment, the housing 6 has two-layer housing main bodies 11a and 11b. The lower housing main body 11a has the cylindrical hollow section 13 vertically penetrating the same, and the entire inner wall surface of the hollow section 13 and part of the base end face 15 of the housing main body 11a are coated with the conductive coat film 12. The upper housing main body 11b has a cylindrical hollow section 48 vertically penetrating the same, and the entire inner wall surface of the hollow section 48 and part of both upper and lower end faces are coated with a conductive coat film 49. The coat film 49 is disposed so as to be in contact with the coat film 12 provided on the base end face 15 of the lower housing main body 11a. In the present embodiment, a base end portion 43 of the probe 5 is comprised of the upper housing main body 11b and the coat film 49. Thus, the diameter of the hollow section 48 in the housing main body 11b is formed smaller than that of the elastic portion 42, and the housing main body 11b comes into contact with the base end side of the elastic portion 42 via the coat film 49. As a result, the position of the elastic portion 42 on the base end side is fixed, and the elastic portion 42 is prevented from going out on the base end side. Moreover, a supporting plate 50 which prevents the leading end portion 41 of the probe 5 from falling off is provided on a lower surface of the lower housing main body 11a, and for example, as shown in the figure, a step is formed between the contact 45 and the axis portion 46 of the leading end portion 41 so that the diameter of the axis portion 46 can be larger, and their step portion 51 can hook on the supporting plate 50.

According to the contact structure 40 comprised of the probe 5 and the housing 6 as described above, an electric current path E passing through the coat films 12 and 49 of the housing 6 from the leading end portion 51 is formed. Moreover, because the spherical or cylindrical elastic portion 42 made of elastomer is vertically elastic, a contact pressure on the subject to be inspected 3 can be obtained, and also, the leading end portion 41 can vertically move.

In the contact structure 40 shown in FIG. 8, the leading end portion 41 may be shaped, for example, as shown in FIG. 9 so that the leading end portion 41 and the coat film 12 of the housing 6 can reliably come into contact with each other. Specifically, a base end face 52 of the leading end portion 41 may be tilted relative to a horizontal direction, and a side face of the shaft portion 46 may be provided with a projection 53 for coming into contact with the coat film 12 so that that the projection 53 can be pressed against and brought into contact with the coat film 12 by the elastic portion 42.

Thus, according to the present invention, miniaturization and performance increase are enabled according to purposes without limitations imposed on the shape and material of the elastic portion.

While the present invention has been described with reference to exemplary preferred embodiments, it is to be understood that the invention is not limited to those exemplary embodiments. It is obvious that a person skilled in the art could have come up with various changes and modifications within the scope of the technical idea described in the claims, and it is to be understood that such changes and modifications shall fall within the technical scope of the present invention.

For example, the material and shape of the elastic portion are not limited to the above described spring shape, spherical shape, cylindrical shape, or the like, but any shape and material may be used as long as the elastic portion is elastic in the direction of the axis of the housing hollow section. Also, for example, when the coat film 12 exposes itself from the base end face of the housing 6 as shown in FIG. 2, the material of the base end portion 23 may not be conductive as long as the entire base end portion 23 of the probe 5 is housed in the hollow section 13 to fix the base end position of the elastic portion 22.

### REFERENCE SIGNS LIST

3 Subject to be inspected
5 Probe
6 Housing
8 Contact structure
11 Housing main body
12 Coat film
13 Hollow section
21 Leading end portion
22 Elastic portion
23 Base end portion
25 Contact

1. A contact structure that comes into contact with a subject to be inspected so as to inspect electrical characteristics of the subject to be inspected, comprising:
a probe and a housing disposed on an outer circumference of said probe,
wherein said housing comprises a housing main body in which a hollow section vertically penetrating the same is formed, and a conductive coat film with which an inner wall surface of the hollow section is coated, and
wherein said probe comprises a base end portion fixed in place on one end side of said housing, a conductive leading end portion that is movable in the hollow section while being in contact with the coat film and has, on a leading end thereof, a contact that comes into contact with the subject to be inspected, and an elastic portion that connects together the base end portion and the leading end portion, is disposed in the hollow section, and has elasticity.

2. A contact structure as claimed in claim 1, wherein said housing is formed by stacking a plurality of layers in a direction of an axis of the hollow section.

3. A contact structure as claimed in claim 1, wherein the elastic portion is formed of an insulating material.

4. A contact structure as claimed in claim 1, wherein the elastic portion is spring-shaped.

5. A contact structure as claimed in claim 1, wherein the leading end portion is disposed such that an axis of the leading end portion is tilted relative to a direction of an axis of the hollow section.

6. A contact structure as claimed in claim 1, wherein a base end face of the leading end portion is tilted relative to a horizontal direction.

7. A contact structure as claimed in claim 1, wherein the elastic portion is made of silicon resin.

8. A method of manufacturing a contact structure that comes into contact with a subject to be inspected so as to inspect electrical characteristics of the subject to be inspected,
the contact structure comprising a probe and a housing disposed on an outer circumference of said probe,
wherein the housing comprises a housing main body in which a hollow section vertically penetrating the same is formed, and a conductive coat film with which an inner wall surface of the hollow section is coated,
wherein the probe comprises a base end portion fixed in place on one end side of said housing, a conductive leading end portion that is movable in the hollow section while being in contact with the coat film and has, on a leading end thereof, a contact that comes into contact with the subject to be inspected, and an elastic portion that connects together the base end portion and the leading end portion, is disposed in the hollow section, and has elasticity, and
wherein the probe is formed by molding the leading end portion and the base end portion by electroforming on a substrate on which a conductive material is laid, forming a mold film on the substrate to form on the mold film a pattern having a shape that matches the elastic portion, and molding the elastic portion into the pattern by electrolytic deposition.

9. A method of manufacturing a contact structure that comes into contact with a subject to be inspected so as to inspect electrical characteristics of the subject to be inspected,
the contact structure comprising a probe and a housing disposed on an outer circumference of said probe,
wherein the housing comprises a housing main body in which a hollow section vertically penetrating the same is formed, and a conductive coat film with which an inner wall surface of the hollow section is coated,
wherein the probe comprises a base end portion fixed in place on one end side of said housing, a conductive leading end portion that is movable in the hollow section while being in contact with the coat film and has, on a leading end thereof, a contact that comes into contact with the subject to be inspected, and an elastic portion that connects together the base end portion and the leading end portion, is disposed in the hollow section, and has elasticity, and
wherein the elastic portion is made of silicon resin, and
wherein the probe is formed by molding the leading end portion and the base end portion by electroforming on a substrate on which a conductive material is laid, forming a mold film on another substrate having a silicon active layer to form on the mold film a pattern having a shape that matches the elastic portion, etching the active layer using the pattern as a mask to mold the elastic portion, and combining the substrate, on which the leading end portion and the base end portion are molded, and the other substrate, on which the elastic portion is molded, together to perform transfer.
